(19) United States
(12) Patent Application Publication
(10) Pub. No.: US 2023/0161556 A1
(43) Pub. Date: May 25, 2023

(54) MEMORY DEVICE AND OPERATION METHOD THEREOF

(71) Applicant: MACRONIX INTERNATIONAL CO., LTD., Hsinchu (TW)

(72) Inventors: Han-Wen Hu, Tainan City (TW); Yung-Chun Li, New Taipei City (TW); Bo-Rong Lin, Taichung City (TW); Huai-Mu Wang, New Taipei City (TW); Wei-Chen Wang, Taipei City (TW)

(21) Appl. No.: 17/701,725

(22) Filed: Mar. 23, 2022

Related U.S. Application Data
(60) Provisional application No. 63/281,734, filed on Nov. 22, 2021.

(51) Int. Cl. G06F 7/544; G06F 7/527; G06F 7/72; G06F 12/0882; G06F 13/16

(52) U.S. Cl. CPC G06F 7/5443; G06F 7/5272; G06F 7/729; G06F 12/0882; G06F 13/1673

(57) ABSTRACT

A memory device and an operation method thereof are provided. The operation method includes: encoding an input data, sending an encoded input data to at least one page buffer, and reading out the encoded input data in parallel; encoding a first part and a second part of a weight data into an encoded first part and an encoded second part of the weight data, respectively, writing the encoded first part and the encoded second part of the weight data into a plurality of memory cells of the memory device, and reading out the encoded first part and the encoded second part of the weight data in parallel; multiplying the encoded input data with the encoded first part and the encoded second part of the weight data respectively to parallel generate a plurality of partial products; and accumulating the partial products to generate an operation result.

This application claims the benefit of U.S. provisional application Ser. No. 63/281,734, filed Nov. 22, 2021, the subject matter of which is incorporated herein by reference.

### TECHNICAL FIELD

The disclosure relates in general to an In-Memory-Computing memory device and an operation method thereof.

### BACKGROUND

Artificial Intelligence (“AI”) has recently emerged as a highly effective solution for many fields. The key issue in AI is that AI contains large amounts of input data (for example input feature maps) and weights to perform multiply-and-accumulate (MAC) operation.

However, the current AI structure usually encounters IO (input/output) bottleneck and inefficient MAC operation flow.

In order to achieve high accuracy, it would perform MAC operations having multi-bit inputs and multi-bit weights. But, the IO bottleneck becomes worse and the efficiency is lower.

In-Memory-Computing (“IMC”) can accelerate MAC operations because IMC may reduce complicated arithmetic logic unit (ALU) in the process centric architecture and provide large parallelism of MAC operation in memory.

In IMC, the unsigned integer multiplication operations and the signed integer multiplication operations are explained as below.

For example, two unsigned 8-bit integers a[7:0] and b[7:0] are multiplied. Eight single-bit multiplication are executed to generate eight partial products p0[7:0]˜p7[7:0], each of the eight partial products are related to each bit of the multiplicand “a”. The eight partial products are expressed as below.
p0[7:0]=a[0]×b[7:0]={8{a[0]}} & b[7:0]
p1[7:0]=a[1]×b[7:0]={8{a[1]}} & b[7:0]
p2[7:0]=a[2]×b[7:0]={8{a[2]}} & b[7:0]
p3[7:0]=a[3]×b[7:0]={8{a[3]}} & b[7:0]
p4[7:0]=a[4]×b[7:0]={8{a[4]}} & b[7:0]
p5[7:0]=a[5]×b[7:0]={8{a[5]}} & b[7:0]
p6[7:0]=a[6]×b[7:0]={8{a[6]}} & b[7:0]
p7[7:0]=a[7]×b[7:0]={8{a[7]}} & b[7:0]
wherein {8{a[0]}} refers to that the bit a[0] is repeated eight times and so on.

In order to generate the dot product, the eight partial products p0[7:0]˜p7[7:0] are accumulated as shown in FIG. 1. FIG. 1A shows multiplication of two unsigned integers (both 8-bit).

Wherein P0=p0[0]+0+0+0+0+0+0+0, and P1=p0[1]+p1[0]+0+0+0+0+0+0, and so on.

The product P[15:0] is generated by accumulating the partial products P0˜P15. The product P[15:0] refers a 16-bit unsigned multiplication product generated from multiplying two unsigned integers (both 8-bit).

However, if the integer b is a signed integer, then before summation, the partial products are sign-extended to the product width. Still further, if the integer “a” is also a signed integer, then the partial product P7 are subtracted from the final sum, rather than added to the final sum.

FIG. 1B shows multiplication of two signed integers (both 8-bit). In FIG. 1B, the symbol “˜” refers to the complement (i.e. an opposite value) of the number, for example, “˜p1[7]” refers to the complement value of p1[7].

In executing IMC, if the operation speed is improved and the memory capacity requirement is lowered, then the IMC performance will be improved.

### SUMMARY

According to one embodiment, provided is a memory device including: a plurality of memory dies, each of the memory die including a plurality of memory planes, a plurality of page buffers and an accumulation circuit, each of the memory planes including a plurality of memory cells. Wherein an input data is encoded; an encoded input data is sent to at least one page buffer of the page buffers; and the encoded input data is read out from the at least one page buffer in parallel; a first part and a second part of a weight data are encoded into an encoded first part and an encoded second part of the weight data, respectively, the encoded first part and the encoded second part of the weight data are written into the plurality of memory cells of the memory device, and the encoded first part and the encoded second part of the weight data are read out in parallel; the encoded input data is multiplied with the encoded first part and the encoded second part of the weight data respectively to parallel generate a plurality of partial products; and the partial products are accumulated to generate an operation result.

According to another embodiment, provided is an operation method for a memory device. The operation method includes: encoding an input data, sending an encoded input data to at least one page buffer, and reading out the encoded input data from the at least one page buffer in parallel; encoding a first part and a second part of a weight data into an encoded first part and an encoded second part of the weight data, respectively, writing the encoded first part and the encoded second part of the weight data into a plurality of memory cells of the memory device, and reading out the encoded first part and the encoded second part of the weight data in parallel; multiplying the encoded input data with the encoded first part and the encoded second part of the weight data respectively to parallel generate a plurality of partial products; and accumulating the partial products to generate an operation result.

### BRIEF DESCRIPTION OF THE DRAWINGS

FIG. 1A (Prior art) shows multiplication of two unsigned integers.

FIG. 1B (Prior art) shows multiplication of two signed integers.

FIG. 2 shows a flow chart of an operation method for a memory device according to one embodiment of the application.

FIG. 3A and FIG. 3B show details of the error-bit-tolerance data encoding according to one embodiment of the application.

FIG. 4A shows 8-bit unsigned integer multiplication operation in one embodiment of the application; and FIG. 4B shows 8-bit signed integer multiplication operation in one embodiment of the application.

FIG. 5A shows unsigned integer multiplication operation in one embodiment of the application; and FIG. 5B shows signed integer multiplication operation in one embodiment of the application.

FIG. 6 shows a functional block of a memory device according to one embodiment of the application.

FIG. 7 shows MAC operation flow comparing one embodiment of the application with the convention art.

FIG. 8 shows an operation method for a memory device according to one embodiment of the application.

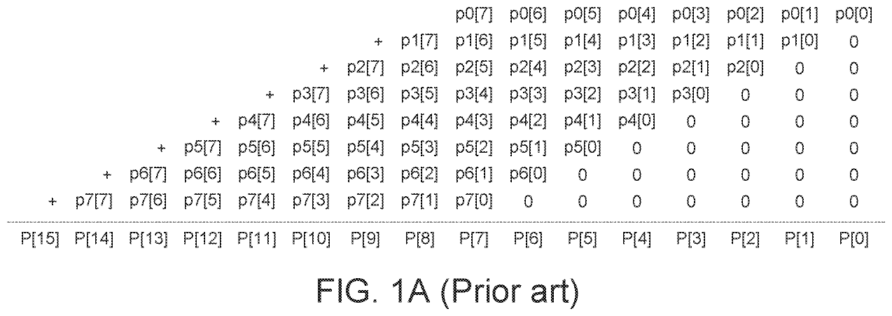

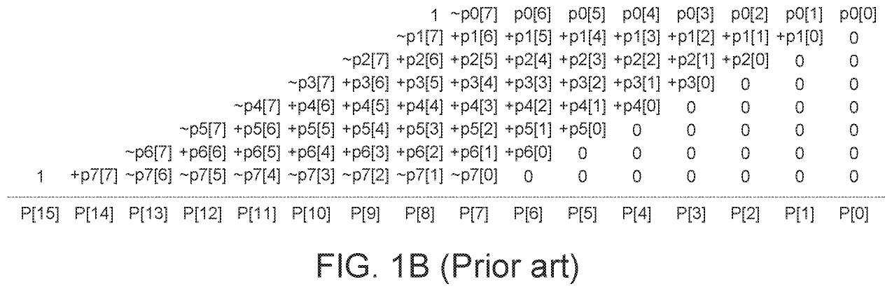

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DESCRIPTION OF THE EMBODIMENTS

Technical terms of the disclosure are based on general definition in the technical field of the disclosure. If the disclosure describes or explains one or some terms, definition of the terms is based on the description or explanation of the disclosure. Each of the disclosed embodiments has one or more technical features. In possible implementation, one skilled person in the art would selectively implement part or all technical features of any embodiment of the disclosure or selectively combine part or all technical features of the embodiments of the disclosure.

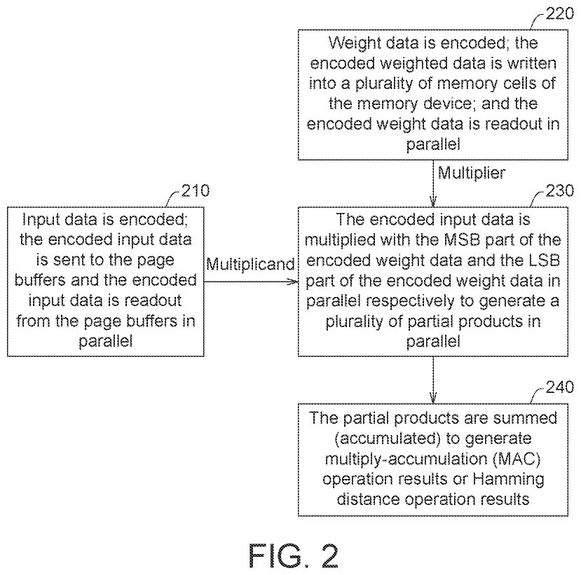

FIG. 2 shows a flow chart of an operation method for a memory device according to one embodiment of the application. In step 210, input data is encoded; the encoded input data (which is a vector) is sent to the page buffers and the encoded input data is read out from the page buffers in parallel, Details of encoding the input data are as follows.

In step 220, weight data is encoded; the encoded weighted data (which is a vector) is written into a plurality of memory cells of the memory device; and the encoded weight data is read out in parallel. In encoding, a most significant bit (MSB) part and a least significant bit (LSB) part of the weight data are independently encoded.

In step 230, the encoded input data is multiplied with the MSB part of the encoded weight data and the LSB part of the encoded weight data in parallel respectively to generate a plurality of partial products in parallel.

In step 240, the partial products are summed (accumulated) to generate multiply-and-accumulation (MAC) operation results or Hamming distance operation results.

One embodiment of the application discloses a memory device implementing digital MAC operations with error-bit-tolerance data encoding to tolerate error bits and reduce area requirements. The error-bit-tolerance data encoding uses input data duplication and weight data flattening techniques. Further, sensing scheme in one embodiment of the application includes standard single level cell (SLC) reading and logic “AND” function to implement bit multiplication for partial product generation. In other possible embodiment of the application, during the sensing procedure, the standard SLC read operation may be replaced by selected-bit-line read or by the standard Multi-Level Cell (MLC)/Triple Level Cell (TLC)/Quad-level cells (QLC) read operation if the page buffer will not remove input data stored in the latch. Further, in one embodiment of the application, the digital MAC operations use high bandwidth weighted accumulator to generation results by reusing the fail-bit-count (FBC) circuits for implementing weighted accumulation.

Another embodiment of the application discloses a memory device implementing Hamming distance computation with error-bit-tolerance data encoding which aims to tolerate error-bits. Error-bit-tolerance data encoding uses input data duplication and weight data flattening techniques. Further, in one embodiment of the application, the sensing scheme comprises the standard SLC read and a logic-XOR function to implement bit multiplication for partial results generation. In other possible embodiment of the application, during the sensing procedure, the standard SLC read operation may be replaced by selected-bit-line read or by the standard Multi-Level Cell (MLC)/Triple Level Cell (TLC)/Quad-level cells (QLC) read operation if the page buffer will not remove input data stored in the latch. Further, the logic-XOR function may be replaced by the logic-XNOR and the logic-NOT function. Further, in one embodiment of the application, the digital Hamming distance computation operations use high bandwidth unweighted accumulator to generation results by reusing the fail-bit-count (FBC) circuits for implementing unweighted accumulation.

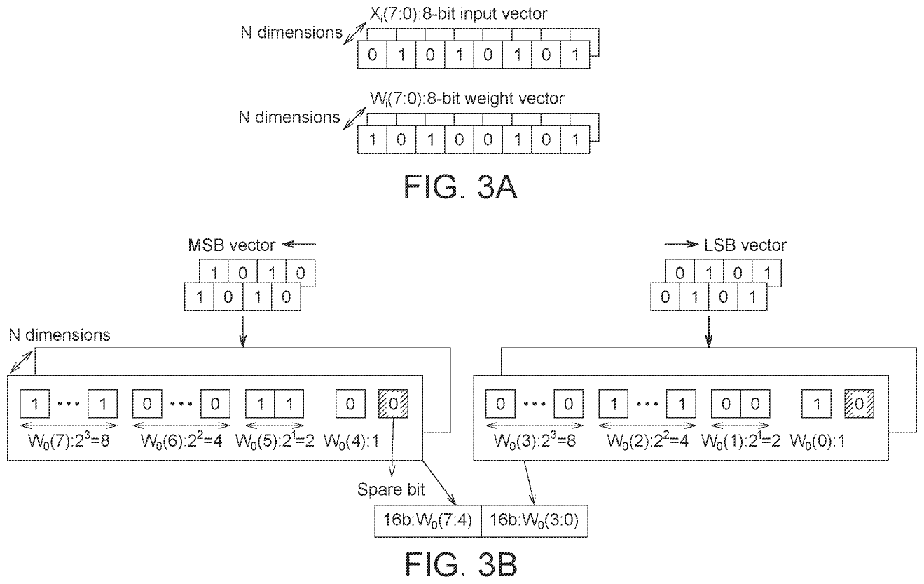

FIG. 3A and FIG. 3B show details of the error-bit-tolerance data encoding according to one embodiment of the application. For example but not limited by, the input data and the weight data are floating point (FP) 32 data. In FIG. 3A, the input data and the weight data are quantized into 8-bit binary integer, wherein the input data and the weight data are both 8-bit vector in N dimensions (N being a positive integer). The input data and the weight data are expressed as Xᵢ(7:0) and Wᵢ(7:0), respectively.

In FIG. 3B, each of the 8-bit weight vectors in the N dimensions are separated into MSB vectors and LSB vectors. The MSB vector of the 8-bit weight vector includes four bits Wᵢ(7:4) and the LSB vector of the 8-bit weight vector includes four bits Wᵢ(3:0).

Each bit of the MSB vector of the 8-bit weight vector and the LSB vector of the 8-bit weight vector is encoded by unary coding (or said value format)). For example, the bit W=ᵢ₌₀(7) of the MSB vector of the 8-bit weight vector is encoded into 8 bits (duplicated 8 times); the bit Wᵢ₌₀(6) of the MSB vector of the 8-bit weight vector is encoded into 4 bits (duplicated 4 times); the bit Wᵢ₌₀(5) of the MSB vector of the 8-bit weight vector is encoded into 2 bits (duplicated 2 times); and the bit Wᵢ₌₀(4) of the MSB vector of the 8-bit weight vector is encoded into 1 bit (duplicated 1 time), and a spare bit (0) is added after the bit Wᵢ₌₀(4) of the MSB vector of the 8-bit weight vector. The four-bit MSB vector of the 8-bit weight vector is encoded into 16 bits in unary coding.

Similarly, the four-bit LSB vector of the 8-bit weight vector is encoded into 16 bits in unary coding.

In one embodiment of the application, via the encoding, the error-bit tolerance is improved.

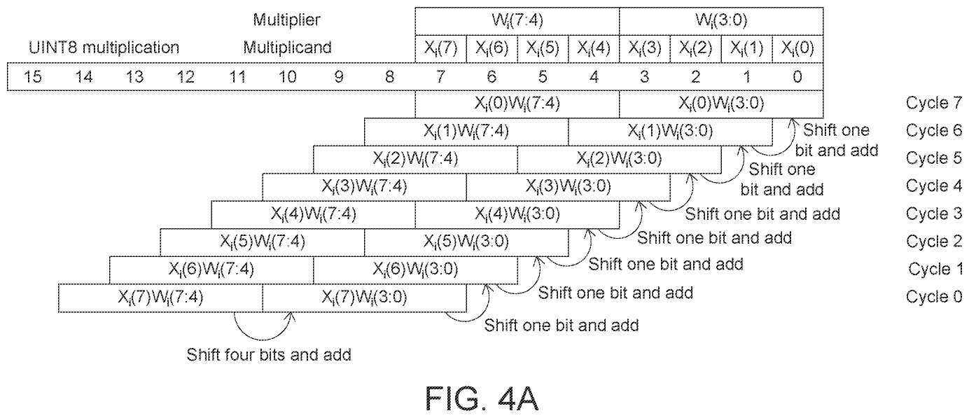

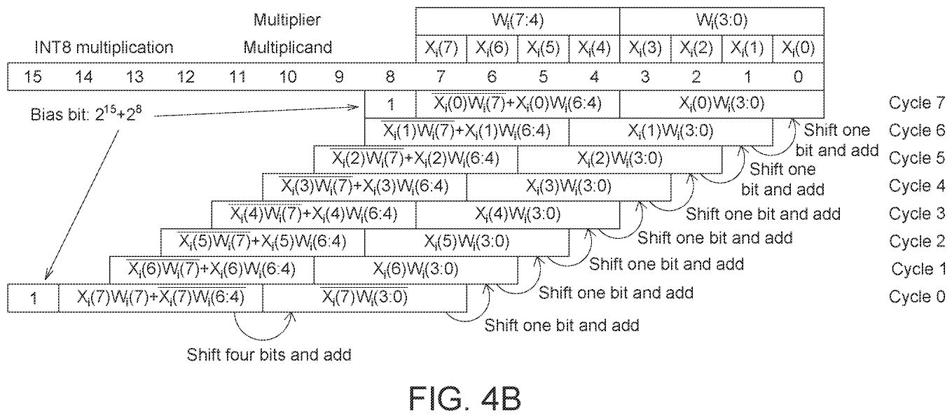

FIG. 4A shows 8-bit unsigned integer multiplication operation in one embodiment of the application; and FIG. 4B shows 8-bit signed integer multiplication operation in one embodiment of the application.

As shown in FIG. 4A, in the 8-bit unsigned integer multiplication operation, in cycle 0, the bit Xᵢ(7) of the input data (the input data is encoded into the unary coding format) is multiplied by the MSB vector W,(7:4) of the weight data (the MSB vector of the weight data is encoded into the unary coding format) to generate a first MSB partial product. Similarly, the bit Xᵢ(7) of the input data is multiplied by the LSB vector Wᵢ(3:0) of the weight data (the LSB vector of the weight data is encoded into the unary coding format) to generate a first LSB partial product. The first MSB partial product is shifted four bits and added to the first LSB partial product to generate a first partial product.

In cycle 1, the bit Xᵢ(6) of the input data is multiplied by the MSB vector Wᵢ(7:4) of the weight data to generate a second MSB partial product. Similarly, the bit Xᵢ(6) of the input data is multiplied by the LSB vector Wᵢ(3:0) of the weight data to generate a second LSB partial product. The second MSB partial product is shifted four bits and added to the second LSB partial product to generate a second partial product. Further, the first partial product is shifted by one bit to add to the second partial product to update the second partial product. Operations of other cycles (cycle 2 to cycle 7) are similar and thus are omitted here.

Thus, 8-bit unsigned integer multiplication operation is completed in eight cycles,

As shown in FIG. 4B, in the 8-bit signed integer multiplication operation, in cycle 0, a first MSB partial product is generated by summing (1) a multiplication result of the bit Xᵢ(7) of the input data with the MSB vector Wᵢ(7) of the weight data and (2) an inverted multiplication result of the bit Xᵢ(7) of the input data with the MSB vector Wᵢ(6:4) of the weight data. The bit Xᵢ(7) of the input data is multiplied by the LSB vector Wᵢ(3:0) of the weight data and the multiplication is inverted to generate a first LSB partial product. The first MSB partial product is shifted four bits and added to the first LSB partial product to generate a first partial product.

In cycle 1, a second MSB partial product is generated by summing (1) an inverted multiplication result of the bit Xᵢ(6) of the input data with the MSB vector Wᵢ(7) of the weight data and (2) a multiplication result of the bit Xᵢ(6) of the input data with the MSB vector Wᵢ(6:4) of the weight data. Similarly, the bit Xᵢ(6) of the input data is multiplied by the LSB vector Wᵢ(3:0) of the weight data to generate a second LSB partial product. The second MSB partial product is shifted four bits and added to the second LSB partial product to generate a second partial product. Further, the first partial product is shifted by one bit to add to the second partial product to update the second partial product. Operations of other cycles (cycle 2 to cycle 7) are similar and thus are omitted here.

Thus, 8-bit signed integer multiplication operation is completed in eight cycles.

In the above example, it takes eight cycles to complete 8-bit signed integer multiplication operation and/or 8-bit unsigned integer multiplication operation.

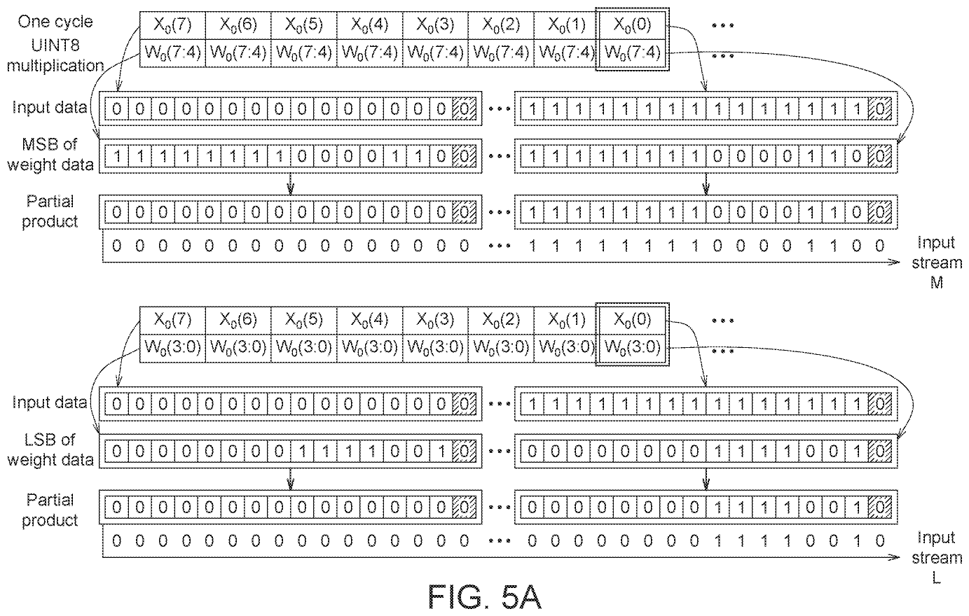

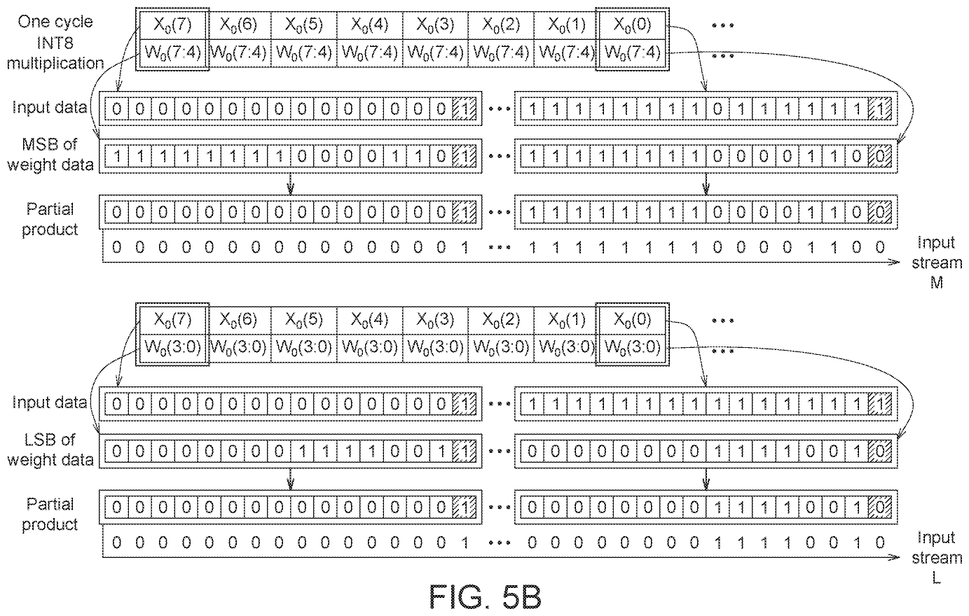

FIG. 5A shows unsigned integer multiplication operation in one embodiment of the application; and FIG. 5B shows signed integer multiplication operation in one embodiment of the application. In FIG. 5A and FIG. 5B, the input data and the weight data are 8-bit as an example, but the application is not limited by this.

In FIG. 5A and FIG. 5B, the MSB vector of the weight data and the LSB vector of the weight data are encoded as unary code format.

In FIG. 5A and FIG. 5B, the input data is input into the page buffers and the weight data is written into a plurality of memory cells.

In FIG. 5A, the input data is read out from the page buffers in parallel and the weight data is read out from the plurality of memory cells in parallel, to perform parallel multiplication for generating a plurality of partial products.

In details, the bit Xᵢ(7) of the input data is multiplied with the MSB vector Wᵢ(7:4) of the weight data to generate a first MSB partial product. The bit Xᵢ(6) of the input data is multiplied with the MSB vector Wᵢ(7:4) of the weight data to generate a second MSB partial product. And so on. The bit Xᵢ(0) of the input data is multiplied with the MSB vector Wᵢ(7:4) of the weight data to generate an eighth MSB partial product. For example, in FIG. 5A, the bit Xᵢ(7) of the input data is duplicated fifteen times and a spare bit is added to form a 16-bit multiplier “0000000000000000”. The 16-bit multiplier “0000000000000000” is multiplied with the MSB vector Wᵢ(7:4) “1111111100001100” of the weight data to generate the first MSB partial product “0000000000000000”. Generation of other MSB partial products are similar. AH the MSB partial products are combined into an input stream M.

Similarly, the bit Xᵢ(7) of the input data is multiplied with the LSB vector Wᵢ(3:0) of the weight data to generate a first LSB partial product. The bit Xᵢ(6) of the input data is multiplied with the LSB vector Wᵢ(3:0) of the weight data to generate a second LSB partial product. And so on. The bit Xᵢ(0) of the input data is multiplied with the LSB vector Wᵢ(3:0) of the weight data to generate an eighth LSB partial product. All the LSB partial products are combined into an input stream L.

The first to the eighth MSB partial products and the first to the eighth LSB partial products are summed; and the number of bit “1” in the summation is counted to generate the MAC operation result of the unsigned multiplication operation.

In FIG. 5B, the input data is read out from the page buffers in parallel and the weight data is read out from the plurality of memory cells in parallel, to perform parallel multiplication for generating a plurality of partial products.

In details, the bit Xᵢ(7) of the input data is multiplied with the MSB vector W(7:4) of the weight data to generate a first MSB partial product. The bit Xᵢ(6) of the input data is multiplied with the MSB vector Wᵢ(7:4) of the weight data to generate a second MSB partial product. And so on. The bit Xᵢ(0) of the input data is multiplied with the MSB vector Wᵢ(7:4) of the weight data to generate an eighth MSB partial product.

Similarly, the bit Xᵢ(7) of the input data is multiplied with the LSB vector Wᵢ(3:0) of the weight data to generate a first LSB partial product. The bit Xᵢ(6) of the input data is multiplied with the LSB vector Wᵢ(3:0) of the weight data to generate a second LSB partial product. And so on. The bit Xᵢ(0) of the input data is multiplied with the LSB vector Wᵢ(3:0) of the weight data to generate an eighth LSB partial product.

The first to the eighth MSB partial products and the first to the eighth LSB partial products are summed; and the number of bit “1” in the summation is counted to generate the MAC operation result of the signed multiplication operation.

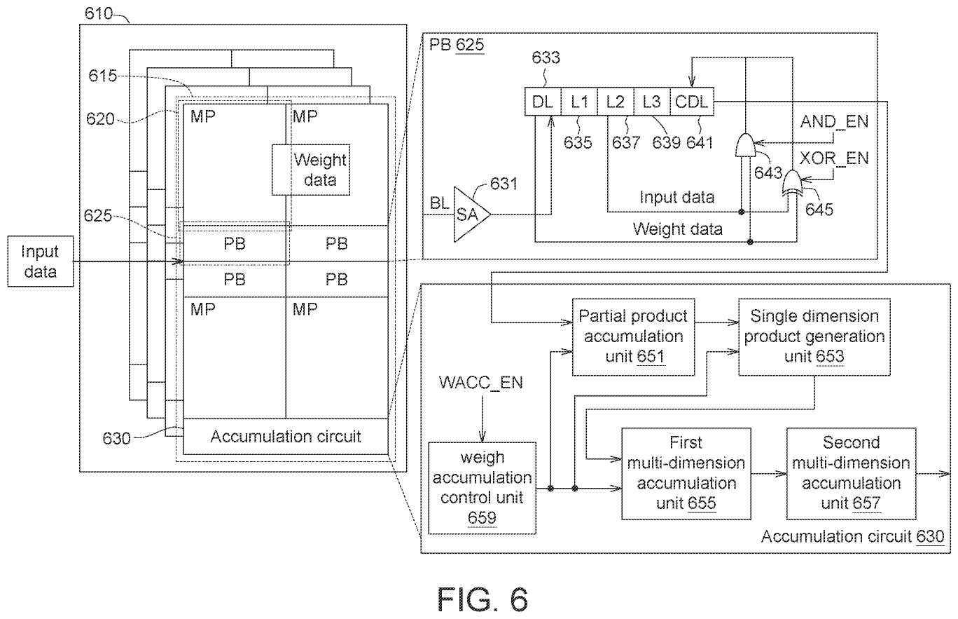

FIG. 6 shows a functional block of a memory device according to one embodiment of the application. The memory device 600 includes a plurality of memory dies 615. In FIG. 6, the memory device 600 inciudes four memory dies 615, but the application is not limited by this.

The memory die 615 includes a plurality of memory planes (MP) 620, a plurality of page buffers (PB) 625 and an accumulation circuit 630. In FIG. 6, the memory die 615 includes four memory planes 620 and four page buffers 625, but the application is not limited by this. The memory plane 620 includes a plurality of memory cells (not shown). The weight data is stored in the memory cells.

In each memory die 615, the accumulation circuit 630 is shared by the memory planes 620 and thus the accumulation circuit 630 sequentially performs the accumulation operations of the memory planes 620. Further, each memory die 615 may independently execute the above digital MAC operations and the digital Hamming distance operations.

The input data is input into the page buffers 625 via a plurality of word lines.

The page buffer 625 includes a sensing circuit 631, a plurality of latch units 633-641 and a plurality of logic gates 643 and 645.

The sensing circuit 631 is coupled to a bit line BL to sense the current on the bit line BL.

The latch units 633-641 are for example but not limited by, a data latch (DL) 633, a latch (L1) 635, a latch (L2) 637, a latch (L3) 639 and a common data latch (CDL) 641. The latch units 633-641 are for example but not limited by, a one-bit latch.

The data latch 633 is for latching the weight data and outputting the weight data to the logic gates 643 and 645.

The latch (L1) 635 and the latch (L3) 639 are for decoding.

The latch (L2) 637 is for latching the input data and sending the input data to the logic gates 643 and 645.

The common data latch (CDL) 641 is for latching the output data form the logic gates 643 and 645.

The logic gates 643 and 645 are for example but not limited by, a logic AND gate and a logic XOR gate. The logic gate 643 performs logic AND operation on the input data and the weight data and writes the logic operation result to the CDL 641. The logic gate 645 performs logic XOR operation on the input data and the weight data and writes the logic operation result to the CDL 641. The logic gates 643 and 645 are controlled by enable signals AND_EN and XOR_EN, respectively. For example, in performing the digital MAC operations, the logic gate 643 is enabled by the enable signal AND_EN; and in performing the digital Hamming distance operations, the logic gate 645 is enabled by the enable signal XOR_EN.

Taking FIG. 5A or FIG. 5B as an example. The bit Xᵢ(7) of the input data is input into the latch (L2) 637 and a bit of the MSB vector Wᵢ(7:4) is input into the data latch 633. The logic gate 643 or 645 perform logic operations on the input data from the latch (L2) 637 and the weight data from the data latch 633 to send the logic operation result to the CDL 641. The CDL 641 is also considered as a data output path of the bit line.

The accumulation circuit 630 includes a partial product accumulation unit 651, a single dimension product generation unit 653, a first multi-dimension accumulation unit 655, a second multi-dimension accumulation unit 657 and a weigh accumulation control unit 659.

The partial product accumulation unit 651 is coupled to the page buffer 625 for receiving a plurality of logic operation results from the plurality of CDLs 641 of the page buffers 625 to generate a plurality of partial products.

For example, in FIG. 5A or FIG. 5B, the partial product accumulation unit 651 generates the first to the eighth MSB partial products and the first to the eighth LSB partial products.

The single dimension product generation unit 653 is coupled to the partial product accumulation unit 651 for accumulating the partial products from the partial product accumulation unit 651 to generate a single dimension product.

For example, in FIG. 5A or FIG. 5B, the single dimension product generation unit 653 accumulates the first to the eighth MSB partial products and the first to the eighth LSB partial products generated from the partial product accumulation unit 651 to generate a single dimension product.

For example, in cycle 0, the product of the dimension <0> is generated by the single dimension product generation unit 653; and in cycle 1, the product of the dimension <1> is generated by the single dimension product generation unit 653, and so on.

The first multi-dimension accumulation unit 655 is coupled to the single dimension product generation unit 653 to accumulate the plurality of single dimension products from the single dimension product generation unit 653 for generating a multi-dimension product accumulation result.

For example but not limited by, the first multi-dimension accumulation unit 655 accumulates products of dimension <0> to dimension <7> from the single dimension product generation unit 653 for generating a product accumulation result of 8-dimension <0:7>. Also, the first multi-dimension accumulation unit 655 accumulates dimension <8> to dimension <15> products from the single dimension product generation unit 653 for generating a product accumulation result of 8-dimension <8:15>.

The second multi-dimension accumulation unit 657 is coupled to the first multi-dimension accumulation unit 655 to accumulate the plurality of multi-dimension products from the first multi-dimension accumulation unit 655 for generating an output accumulation value. For example but not limited by, the second multi-dimension accumulation unit 657 accumulates sixty-four 8-dimension products from the first multi-dimension accumulation unit 655 for generating a 512-dimension output accumulation value.

The weigh accumulation control unit 659 is coupled to the partial product accumulation unit 651, the single dimension product generation unit 653 and the first multi-dimension accumulation unit 655. Based on whether either the digital MAC operation or the digital Hamming distance operation is performed, the weigh accumulation control unit 659 is enabled or disabled, For example but not limited by, when the digital MAC operation is performed, the weigh accumulation control unit 659 is enabled; and when the digital Hamming distance operation is performed, the weigh accumulation control unit 659 is disabled. When the weigh accumulation control unit 659 is enabled, the weigh accumulation control unit 659 is enabled based on the weight accumulation enable signal WACC_EN for outputting control signals to the partial product accumulation unit 651, the single dimension product generation unit 653 and the first multi-dimension accumulation unit 655.

The single page buffer 620 in FIG. 6 is coupled to a plurality of bit lines BL. For example but not limited by, each page buffer 620 is coupled to 131072 bit lines BL, and 128 bit lines BL are selected in each cycle to send data to the accumulation circuit 630 for accumulation. By so, it needs 1024 cycles to send data on 131072 bit lines BL.

In the above description, the partial product accumulation unit 651 receives 128 bits in one cycle, the first multi-dimension accumulation unit 655 generates sixty-four 8-dimension products and the second mufti-dimension accumulation unit 657 generates a 512-dimension output accumulation value. But the application is not limited by this. In another possible embodiment, the partial product accumulation unit 651 receives 64 bits (2 bits in one set) in one cycle, the first multi-dimension accumulation unit 655 generates three-two 16-dimension products and the second multi-dimension accumulation unit 657 generates a 512-dimension output accumulation value.

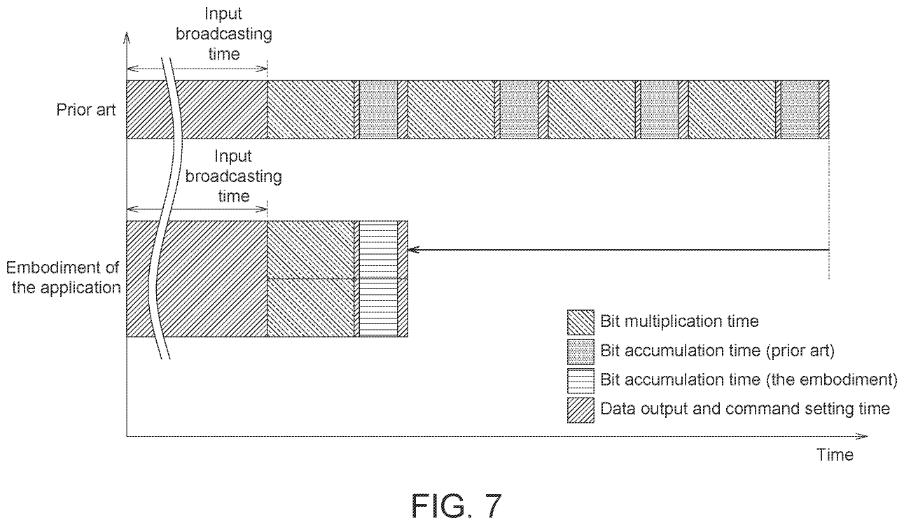

FIG. 7 shows MAC operation flow comparing one embodiment of the application with the convention art. In FIG. 7, during the input broadcasting timing, the input data is received. The input data and the weight data are multiplied and accumulated as described above to generate digital MAC operation result.

In the conventional art, it needs long operation time; but in one embodiment of the application, the parallel bit-multiplication is for generating (1) the partial products of the input vector and the MSB vector of the weight data; and (2) the partial products of the input vector and the LSB vector of the weight data. Thus, in one embodiment of the application, the unsigned multiplication operation and/or the signed multiplication operation is completed in one cycle. Therefore, one embodiment of the application has faster operation speed than the conventional art.

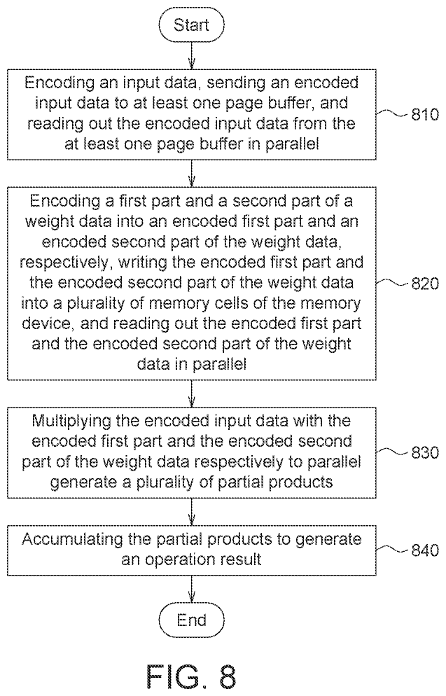

FIG. 8 shows an operation method for a memory device according to one embodiment of the application. The operation method for a memory device according to one embodiment of the application includes: encoding an input data, sending an encoded input data to at least one page buffer, and reading out the encoded input data from the at least one page buffer in parallel (810); encoding a first part and a second part of a weight data into an encoded first part and an encoded second part of the weight data, respectively, writing the encoded first part and the encoded second part of the weight data into a plurality of memory cells of the memory device, and reading out the encoded first part and the encoded second part of the weight data in parallel (820); multiplying the encoded input data with the encoded first part and the encoded second part of the weight data respectively to parallel generate a plurality of partial products (830); and accumulating the partial products to generate an operation result (840).

As described above, in one embodiment of the application, via the error-bit tolerance data encoding technology, the error bits are reduced, the accuracy is improved and the memory capacity requirement is also reduced.

Further, in one embodiment of the application, the digital MAC operation generates the output result by using high bandwidth weighted accumulator which implements weighted accumulation by reusing the fail bit counting circuit, thus the accumulation speed is improved.

Further, in one embodiment of the application, the digital Hamming distance operation generates the output result by using high bandwidth unweighted accumulator which implements unweighted accumulation by reusing the fail bit counting circuit, thus the accumulation speed is improved.

The embodiments of the application are applied to NAND type flash memory, or the memory device sensitive to the error bits, for example but not limited by, NOR type flash memory, phase changing memory, magnetic RAM or resistive RAM.

In one embodiment of the application, the accumulation circuit 630 receives 128 partial products from the page buffer 625, but in other embodiment of the application, the accumulation circuit 630 receives 2, 4, 8, 16, 512 (which is the power of 2) partial products from the page buffer 625, which is still within the spirit and the scope of the application.

In the above embodiment, the accumulation circuit 630 supports the addition function, but in other possible embodiment, the accumulation circuit 630 supports subtraction function, which is still within the spirit and the scope of the application.

In the above embodiment, the INT8 or UINT8 digital MAC operation is taken as an example, but other possible embodiment also supports INT2, UINT2, INT4 or UINT4 digital MAC operation, which is still within the spirit and the scope of the application.

Although in the embodiments of the application, the weight are divided into the MSB vector and the LSB vector (i.e. two vectors), but the application is not limited by this. In other possible embodiment of the application, the weight are divided into more vectors, which is still within the spirit and the scope of the application.

The embodiments of the application are not only applied to AI model design that needs to perform MAC operation, but also applied to other AI technologies, such as fully-connection layer, convolution layer, multiple layer Perceptron, support vector machine.

The embodiments of the application are not only applied to computing usage but also to similarity search, analysis usage, clustering analysis and so on.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A memory device including;
a plurality of memory dies, each of the memory die including a plurality of memory planes, a plurality of page buffers and an accumulation circuit, each of the memory planes including a plurality of memory cells;
wherein
an input data is encoded; an encoded input data is sent to at least one page buffer of the page buffers; and the encoded input data is read out from the at least one page buffer in parallel;
a first part and a second part of a weight data are encoded into an encoded first part and an encoded second part of the weight data, respectively, the encoded first part and the encoded second part of the weight data are written into the plurality of memory cells of the memory device,and the encoded first part and the encoded second part of the weight data are read out in parallel;
the encoded input data is multiplied with the encoded first part and the encoded second part of the weight data respectively to parallel generate a plurality of partial products; and
the partial products are accumulated to generate an operation result.

2. The memory device according to claim 1, wherein:
the encoded first part and the encoded second part of the weight data are most significant bits (MSB) and least significant bits (LSB) of the weight data,respectively.

3. The memory device according to claim 1, wherein:
in encoding, the input data and the weight data are quantized as binary integer vectors;
each bit of the input data is duplicated a plurality of times and a spare bit is added;
the weight data is separated into the first part and the second part; and
each bit of the first part and the second part of the weight data is encoded into unary coding format to generate the encoded first part and the encoded second part of the weight data.

4. The memory device according to claim 1, wherein the operation result includes a multiply-and-accumulate (MAC) operation result or a Hamming distance operation result.

5. The memory device according to claim 4, wherein
in performing MAC operation, each bit of the encoded input data and each bit of the encoded first part of the weight data are performed by logic AND operations; and
in performing Hamming distance operation, each bit of the encoded input data and each bit of the encoded first part of the weight data are performed by logic XOR operations.

6. The memory device according to claim 1, wherein
the partial products of the same dimension are accumulated to generate a single-dimension product;
a plurality of single-dimension products are accumulated to generate a multi-dimension product accumulation result; and
a plurality of multi-dimension product accumulation results are accumulated to generate the operation result.

7. An operation method for a memory device, the operation method including:
encoding an input data, sending an encoded input data to at least one page buffer, and reading out the encoded input data from the at least one page buffer in parallel;
encoding a first part and a second part of a weight data into an encoded first part and an encoded second part of the weight data, respectively, writing the encoded first part and the encoded second part of the weight data into a plurality of memory cells of the memory device, and reading out the encoded first part and the encoded second part of the weight data in parallel;
multiplying the encoded input data with the encoded first part and the encoded second part of the weight data respectively to parallel generate a plurality of partial products; and
accumulating the partial products to generate an operation result.

8. The operation method for memory device according to claim 7, wherein:
the encoded first part and the encoded second part of the weight data are most significant bits (MSB) and least significant bits (LSB) of the weight data, respectively.

9. The operation method for memory device according to claim 7, wherein:
in encoding, the input data and the weight data are quantized as binary integer vectors;
each bit of the input data is duplicated a plurality of times and a spare bit is added;
the weight data is separated into the first part and the second part; and
each bit of the first part and the second part of the weight data is encoded into unary coding format to generate the encoded first part and the encoded second part of the weight data.

10. The operation method for memory device according to claim 7, wherein the operation result includes a multiply-and-accumulate (MAC) operation result or a Hamming distance operation result.

11. The operation method for memory device according to claim 10, wherein
in performing MAC operation, each bit of the encoded input data and each bit of the encoded first part of the weight data are performed by logic AND operations; and
in performing Hamming distance operation, each bit of the encoded input data and each bit of the encoded first part of the weight data are performed by logic XOR operations.

12. The operation method for memory device according to claim 7, wherein
the partial products of the same dimension are accumulated to generate a single-dimension product;
a plurality of single-dimension products are accumulated to generate a multi-dimension product accumulation result; and
a plurality of multi-dimension product accumulation results are accumulated to generate the operation result.
